(19) United States
(12) Patent Application Publication
(10) Pub. No.: US 2024/0051192 A1
(43) Pub. Date: Feb. 15, 2024

(54) COVER MEMBER, MOLD DEVICE, AND ELECTRONIC DEVICE

(71) Applicant: Hitachi Astemo, Ltd., Hitachinaka-shi, Ibaraki (JP)

(72) Inventors: Yudai MIYAZAWA, Hitachinaka-shi, Ibaraki (JP); Kumiko YOSHINAGA, Hitachinaka-shi, Ibaraki (JP); Kentaro YAMANAKA, Hitachinaka-shi, Ibaraki (JP)

(73) Assignee: Hitachi Astemo, Ltd., Hitachinaka-shi, Ibaraki (JP)

(21) Appl. No.: 18/259,560

(22) PCT Filed: Dec. 15, 2021
(86) PCT No.: PCT/JP2021/046173

§ 371 Date: Jun. 27, 2023

(30) Foreign Application Priority Data
Dec. 28, 2020 (JP) 2020-218158

(51) Int. Cl. B29C 39/26; B29C 45/40; H05K 5/00; H05K 5/03

(52) U.S. Cl. CPC B29C 39/26; B29C 45/401; H05K 5/0052; H05K 5/03

(57) ABSTRACT

A cover (5) of an electronic device has side walls (8) and a ceiling wall (9), and is molded by injection molding using a mold. The ceiling wall (9) has a flat plate shape. Disk-shaped thick portions (21) that locally protrude inward so as to be relatively thicker than an adjacent normal portion of the ceiling wall (9) are provided at a plurality of positions of the ceiling wall (9) corresponding to respective positions of ejection by ejection pins (25). Although a circular dent (22) is formed at a middle of the thick portion (21) due to the thick portion (21) being pressed by a tip of the ejection pin (25), even at this dent (22) portion, a thickness equal to or greater than that of the normal portion of the ceiling wall (9) is secured.

### TECHNICAL FIELD

The present invention relates to a cover member molded from synthetic resin material, a mold device for molding this cover member, and an electronic device using this cover member.

### BACKGROUND ART

For instance, as various controllers mounted on a vehicle, there is known a configuration in which a circuit board mounting thereon electronic components is accommodated in an internal space of a cabinet formed by combining a metal case body and a synthetic resin cover. The cover of such cabinet is usually has a dish-like shape having a ceiling wall that faces the circuit board and side walls that surround the ceiling wall in order to secure a space for accommodating the circuit board between the cover and the case body. For instance, the cover is molded using a mold by a technique such as injection molding.

In resin molding using the mold, in order to release a molded product from a mold surface of the mold after opening the mold, a mold device is generally provided with an ejection pin that pushes out or ejects the molded product. That is, the ejection pin moves parallel to opening/closing directions of the mold and protrudes from the mold surface, then the molded product is pushed by the ejection pin and is released from the mold.

Patent Document 1 discloses a configuration in which a tip surface, which is exposed on the mold surface of the mold, of the ejection pin is spherically rounded.

In recent years, regarding the synthetic resin cover of the cabinet of an electronic device etc., thinning of the ceiling wall has been required in order to reduce outer dimensions as much as possible while securing the internal space. In response to such demand, when a thickness of the ceiling wall becomes thinner to the limit, a stamp-like dent generated in the molded product at a time of ejection of the ejection pin poses a new problem in securing the strength of the cover. That is, since the ejection of the molded product by the ejection pin is done before the molded product is completely cooled and hardened, the tip surface of the ejection pin presses against a surface of the molded product, then the stamp-like dent is generated, and as a consequence, the surface of the molded product is locally further thinner. Therefore, if the thickness of the ceiling wall is made as thin as possible, a thickness of a portion pressed by the tip surface of the ejection pin will be insufficient, and there is a risk that a product lacking the strength will be produced.

Patent Document 1 cannot solve such problem of the dent generated when pushing out the molded product by the ejection pin.

### CITATION LIST

### Patent Document

Patent Document 1: Japanese Unexamined Patent Application Publication No. 2000-334760

### SUMMARY OF THE INVENTION

According to the present invention, as an aspect of the present invention, a cover member is provided, at a plurality of positions of a ceiling wall corresponding to respective positions of ejection by ejection pins when releasing the cover member from a mold, with thick portions which locally protrude inward so as to be relatively thicker than an adjacent normal portion of the ceiling wall.

With this configuration, even if a stamp-like dent is generated by the ejection pin due to the thick portion being pressed by a tip surface of the ejection pin when the cover member is released from the mold, a thickness equal to or greater than that of a surrounding normal portion of the ceiling wall can be secured, and decrease in strength can be prevented. Therefore, a thickness of the ceiling wall itself other than the thick portions can be sufficiently thin.

### BRIEF DESCRIPTION OF THE DRAWINGS

FIG. 1 is an exploded perspective view of an electronic device of a first embodiment.

FIG. 2 is a plan view of a cover, viewed from its inside, of the first embodiment.

FIG. 3 is a sectional view taken along an A-A line of FIG. 2.

FIG. 4 is an enlarged sectional view of a thick portion, depicted by enlarging an E-part of FIG. 3.

FIG. 5 is an enlarged plan view of the thick portion.

FIG. 6 is an enlarged sectional view of the thick portion before contact with an ejection pin.

FIG. 7 is an enlarged plan view of the thick portion, showing an example in which a dent generated due to the contact of an ejection pin is misaligned.

FIG. 8 is a sectional view of a respiration filter portion.

FIG. 9 is a front view of the respiration filter portion, viewed along an arrow B direction of FIG. 8.

FIG. 10 is an explanatory drawing showing a positional relationship between a gate position, final arrival points of resin material and the thick portions at a time of molding.

FIG. 11 is a sectional view of an assembled electronic device.

FIG. 12 is a plan view of a cover, viewed from its inside, of a second embodiment.

FIG. 13 is a sectional view taken along a C-C line of FIG. 12.

FIG. 14 is an enlarged sectional view of the thick portion, depicted by enlarging an F-part of FIG. 13.

FIG. 15 is an enlarged sectional view of the thick portion before contact with the ejection pin.

FIG. 16 is a plan view of a cover, viewed from its inside, of a third embodiment.

FIG. 17 is an explanatory drawing showing a dimensional relationship between the ejection pin and the thick portion.

FIG. 18 is a perspective view of a mold device for molding the cover of the first embodiment.

FIG. 19 is an explanatory drawing showing an opening state of the mold device.

FIG. 20 is an explanatory drawing depicted by enlarging a D-part of FIG. 19.

### EMBODIMENTS FOR CARRYING OUT THE INVENTION

Embodiments of the present invention will be described in detail below with reference to the drawings.

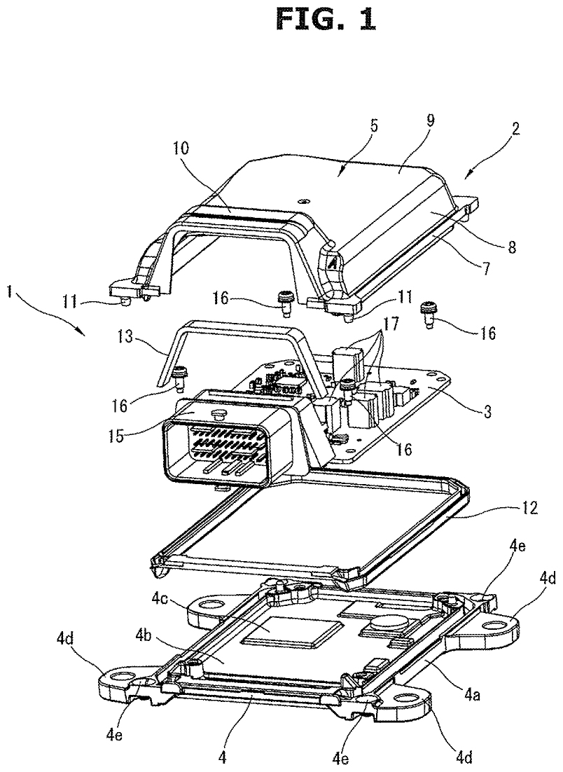

FIG. 1 is an exploded perspective view of an electronic device 1 of a first embodiment. This electronic device 1 is installed at an appropriate position in a vehicle, for instance, as a controller of an automatic transmission for the vehicle. The electronic device 1 has a cabinet 2 and a circuit board 3 accommodated in an internal space of this cabinet 2.

The cabinet 2 is formed by a substantially rectangular base 4 made of metal such as aluminium and a synthetic resin cover 5 having a swollen shape so as to cover the circuit board 3 accommodated in the cabinet 2. In this embodiment, the base 4 and the cover 5 correspond to “case” and “cover member” in claims respectively.

The base 4 has a relatively thin rectangular plate shape. The base 4 is formed as a die-cast product made of metal material such as aluminium. The base 4 has, at a periphery thereof, a flange portion 4a along one plate. A central part 4b enclosed with this flange portion 4a is slightly recessed toward an opposite side to the cover 5. This central part 4b substantially corresponds to an area where the circuit board 3 is placed. A heat sink portion 4c, which slightly swells, is formed as appropriate in the central part 4b. This heat sink portion 4c is in absolute contact with a heat-generating component (not shown) attached to the circuit board 3 through, for instance, heat-radiating grease, and functions as a heat sink. The base 4 also has a total of four mounting pieces 4d for mounting the electronic device 1 as a whole to a vehicle body. Further, circular mounting holes 4e for fixing the cover 5 to the base 4 are opened at four corners of the base 4.

The cover 5 is molded as a single-piece component from thermoplastic synthetic resin material such as polyamide resin, and has a rectangular box-like or deep dish-like shape whose surface facing the base 4 is open. More specifically, the cover 5 has, at three sides of a peripheral edge thereof, flange portions 7 corresponding to the flange portion 4a of the base 4, and a substantially flat ceiling wall 9 and the flange portions 7 are connected through side walls 8 that obliquely stand from the respective flange portions 7. The remaining one side of the cover 5 is provided with a bulging portion 10 that is open so as to receive an after-described connector 15. The ceiling wall 9 extends along a plane substantially parallel to a plane along which the flange portions 7 extend.

At four corners of the flange portions 7, heat caulking pins (or heat riveting pins) 11 that project in a direction orthogonal to respective surfaces of the flange portions 7 are provided. These heat caulking pins 11 are located at positions corresponding to the respective mounting holes 4e of the base 4. By inserting the heat caulking pins 11 into the respective mounting holes 4e and heating/pressurizing the heat caulking pins 11 from the outside of the base 4, each heat caulking pin 11 is brought to a caulking state (or a riveting state) as a so-called thermal caulking (or thermal riveting). In an assembled state of the electronic device 1, the base 4 and the cover 5 are firmly connected by this thermal caulking (or thermal riveting) at these four positions. In FIG. 1, the heat caulking pins 11 before heat caulking process are depicted.

A gap between the base 4 and the cover 5 is sealed by a gasket 12 provided along the flange portions 4a and 7. Further, a gasket 13 is also provided around the connector 15, and a gap between the bulging portion 10 of the cover 5 and the connector 15 is sealed by this gasket 13.

The circuit board 3 is a printed wiring board using a resin board such as glass epoxy resin or a metal boar. The circuit board 3 has a rectangular shape corresponding to a shape of the cabinet 2. The synthetic resin connector 15 for bringing a power line and signal lines together and connecting them to the circuit board 3 is fixed to one end portion in a longitudinal direction of the circuit board 3. In the assembled state of the electronic device 1, a part of the connector 15 is exposed to the outside through an opening between the bulging portion 10 of the cover 5 and the base 4.

The circuit board 3 is fixed to the base 4 with screws 16 disposed at four corners of the circuit board 3. This circuit board 3 mounts thereon a number of electronic components including a CPU(s), an IC(s), a resistor(s), a capacitor(s) and so on. In the drawing, only a part of a number of electronic components is depicted. In these electronic components, a plurality of (e.g. four) electrolytic capacitors 17 are included as electronic components having a maximum (highest) height from the circuit board 3. In the illustrated example, the electrolytic capacitors 17 each have a prismatic shape, and a predetermined clearance is required between a top surface of each electrolytic capacitor 17 and an inner surface of the cover 5 so that gas can be emitted for explosion protection.

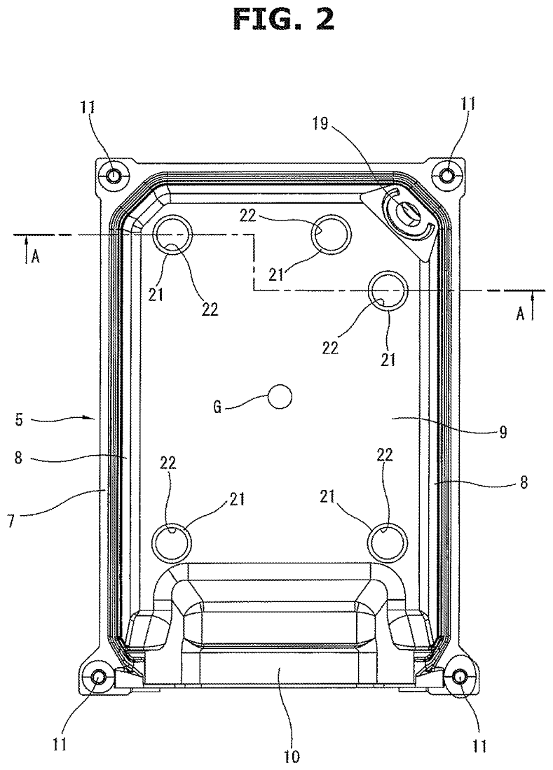

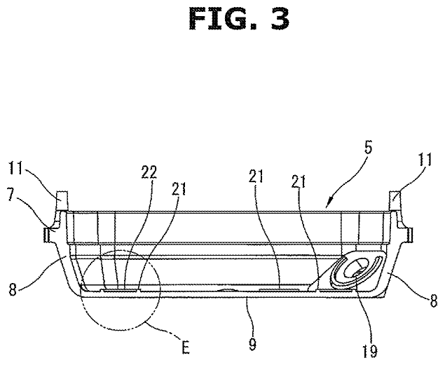

Next, a configuration of the cover 5, which is a main part of the present invention, will be described with reference to FIGS. 2 to 6. FIG. 2 is a plan view of the cover 5, viewed from its inside (from the circuit board 3 side), of the first embodiment. FIG. 3 is a sectional view taken along an A-A line of FIG. 2. The cover 5 as a whole is molded as an integral component by die molding such as injection molding.

As illustrated in FIGS. 2 and 3, the substantially rectangular ceiling wall 9 enclosed with the side walls 8 at the three sides and the bulging portion 10 at the remaining one side is formed into a flat plate shape parallel to the base 4 and the circuit board 3, and basically has a constant thickness. In the present embodiment, thick portions 21 each having a circular shape in plan view are provided at a plurality of positions (five positions in the illustrated example) that are close to the side walls 8 at a periphery of the ceiling wall 9. These thick portions 21 are formed so that the thick portions 21 locally protrude inward so as to be relatively thicker than a normal portion of the ceiling wall 9 which is adjacent to the thick portions 21. On an outer surface of the ceiling wall 9, there is no asperity or unevenness associated with formation of the thick portions 21, and thus the outer surface of the ceiling wall 9 is a flat surface.

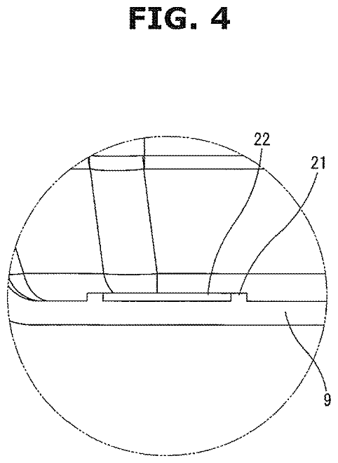

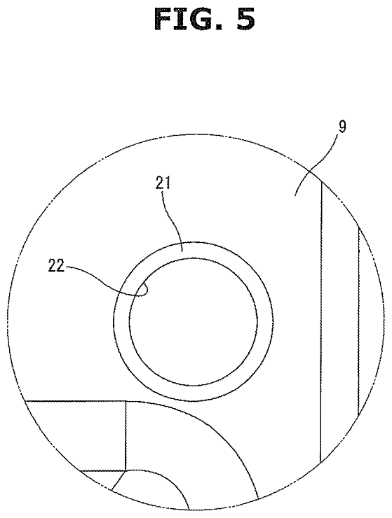

The thick portions 21 protruding toward an inside of the cover 5 in a shape of a disk in this manner are arranged at positions corresponding to respective positions of ejection by ejection pins provided in a mold device at a time of the injection molding. FIG. 4 is an enlarged sectional view of the thick portion 21, and FIG. 5 is an enlarged plan view of the thick portion 21. In one embodiment, the ejection pin has a shape of a round bar, and the thick portion 21 has a size that embraces or encompasses an ejection surface of the ejection pin (i.e. a tip surface of the ejection pin which is in contact with a molded product). Since the ejection by the ejection pin is carried out before the molded product is completely cooled and hardened, the tip of the ejection pin presses against the thick portion 21, then a circular dent 22 is formed at a middle of the thick portion 21. A depth of this dent 22 is slightly different due to or depending on manufacturing variations (for instance, variations in temperature of the molded product during the ejection by the ejection pin). It is noted that the sectional view of FIG. 4 illustrates a case where the dent 22 is formed at the maximum depth. As illustrated in the drawing, a thickness of the ceiling wall 9 at a portion of the dent 22 is set so as to be equal to a thickness of the surrounding normal portion when the depth of the dent 22 is the assumed maximum depth. In other words, as the thickness of the ceiling wall 9 at the portion of the dent 22, a thickness equal to or greater than that of the normal portion is secured even if the manufacturing variations occur.

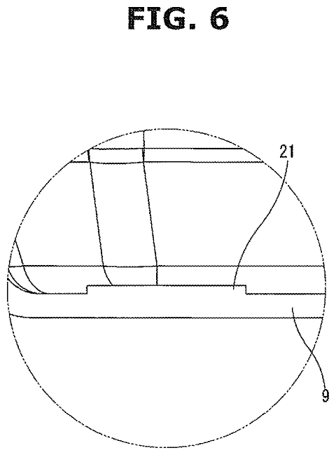

FIG. 6 is an enlarged sectional view of the thick portion 21 before contact with the ejection pin, and in the mold, the thick portion 21 is molded into a disk shape illustrated in FIG. 6. Then, as a final product after the ejection by the ejection pin, as depicted in FIGS. 4 and 5, the thick portion 21 has an annular shape having the dent 22.

As described above, by providing the thick portion 21 at the position corresponding to the ejection position of the ejection pin, even if the dent 22 is formed due to the thick portion 21 being pressed by the ejection pin, the ceiling wall 9 is not locally excessively thin, and there is no concern about decrease in strength due to the dent 22. Therefore, the ceiling wall 9 can be made sufficiently thin.

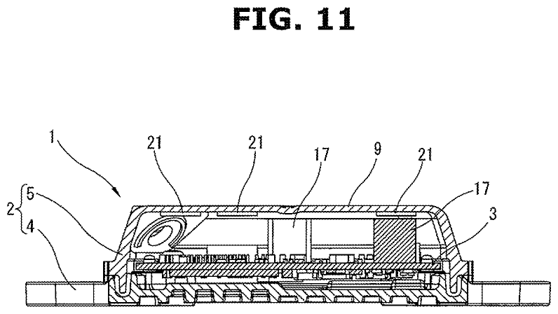

FIG. 11 is a sectional view of the electronic device 1 having the cover 5 of the first embodiment, and particularly illustrates a relationship of height between the electrolytic capacitor 17 of the electronic component whose height from the circuit board 3 is the maximum and the inner surface of the ceiling wall 9 of the cover 5. As illustrated in FIG. 11, as compared with the height size of the electrolytic capacitor 17, a distance from the circuit board 3 at the thick portion 21 up to a surface of the thick portion 21 is set to be slightly great. Here, arrangement of the electrolytic capacitor 17 and the thick portion 21 are set so that these electrolytic capacitor 17 and thick portion 21 do not overlap each other when the electronic device 1 is seen through from a direction orthogonal to the circuit board 3. That is, the top surface of the electrolytic capacitor 17 faces the normal portion of the ceiling wall 9 other than the thick portion 21, and a sufficient clearance is secured between the electrolytic capacitor 17 and the normal portion of the ceiling wall 9.

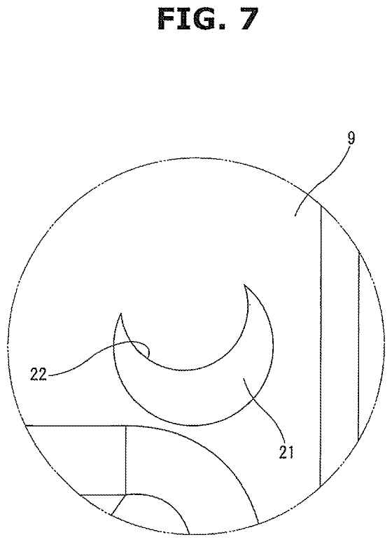

The thick portion 21 of the first embodiment also contributes to judgment about whether the ejection pin properly or correctly ejects the molded product. That is, as shown in FIGS. 4 and 5, since the round bar-shaped ejection pin and the circular thick portion 21 are arranged or set concentrically, when the dent 22 is formed, the thick portion 21 remains in the annular shape. On the other hand, if the ejection position of the ejection pin shifts or deviates due to distortion etc. of the molded product when releasing the molded product from the mold, as illustrated in FIG. 7, the dent 22 is not formed concentrically, but gets misaligned or is offset with respect to an outer circle of the thick portion 21. In an extreme case, as shown in the drawing, the thick portion 21 remains in a crescent shape.

When the dent 22 is offset with respect to the thick portion 21 in this manner, since the molded product is not properly ejected, distortion of the molded product may occur and/or the molded product may be unintentionally thinned locally. Therefore, by visually or optically judging whether an outline of the thick portion 21 is formed in a circular shape, it is possible to easily weed out a defective product.

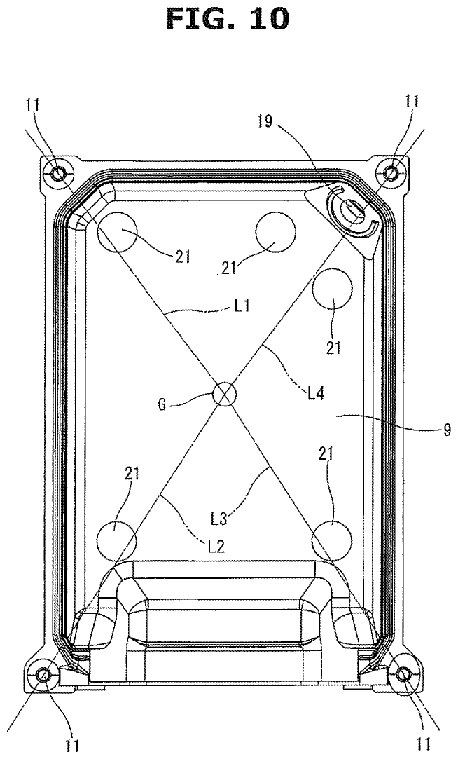

FIG. 10 is an explanatory drawing showing a positional relationship between a gate position G, final arrival points of resin material and the thick portions 21 at a time of the molding. As shown by a reference sign G in FIG. 10, a gate that serves as an injection port of molten resin (or fused resin) during the injection molding is positioned substantially at the center of the ceiling wall 9 of the cover 5 of the present embodiment. The molten resin material (or the fused resin material) flows radially from this gate position G. Then, final arrival points of the resin material are the heat caulking pins 11 arranged at the four corners of the cover 5.

The thick portions 21 are basically located between the gate position G and the heat caulking pins 11 of the final arrival points. More specifically, the thick portions 21 are arranged on straight lines L1 to L4 that connect the gate position G and the heat caulking pins 11. However, since a circular opening 19 that is a respiration filter portion is provided on the straight line L4, the configuration is different. The other three thick portions 21 are located on the straight lines L1, L2 and L3 respectively. As described above, since the thick portions 21 where a volume or a space of a cavity expands or is enlarged exist between the gate position G and the final arrival points of the resin material, flow of the resin is improved. Therefore, shortage of the resin material is less likely to occur around the final arrival points, and also a time required to complete filling the resin material is shortened, then a cycle time can be shortened.

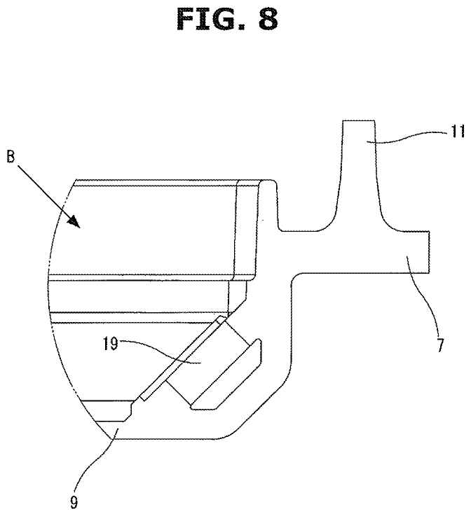

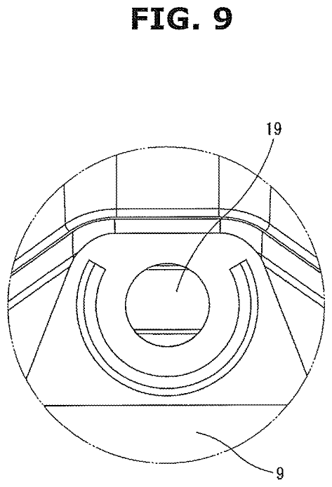

FIG. 8 is a sectional view of the respiration filter portion, and FIG. 9 is a front view of the respiration filter portion, viewed along an arrow B direction of FIG. 8. The opening 19 serving as the respiration filter portion is located at one corner portion of the cover 5. As illustrated in FIGS. 8 and 9, the side wall 8 is formed thicker, then the opening 19 is formed with the opening 19, which is circular in cross section, penetrating this side wall 8. Here, finally, a water-repellent filter film (not shown) is attached to an end surface of the opening 19 inside the cover 5.

As described above, since the opening 19 is positioned between the gate position G and the heat caulking pin 11 and a periphery of the opening 19 is thicker, as for the straight line L4, the pair of thick portions 21 are arranged on both sides of the straight line L4. These two thick portions 21 are arranged at positions that are as symmetrical as possible on opposite sides of the straight line L4. Therefore, the resin material flows to the heat caulking pin 11 of the final arrival point while flowing around the opening 19 from both sides of the opening 19 through the pair of thick portions 21. With this, good flow of the resin is realized also in the vicinity of the respiration filter portion.

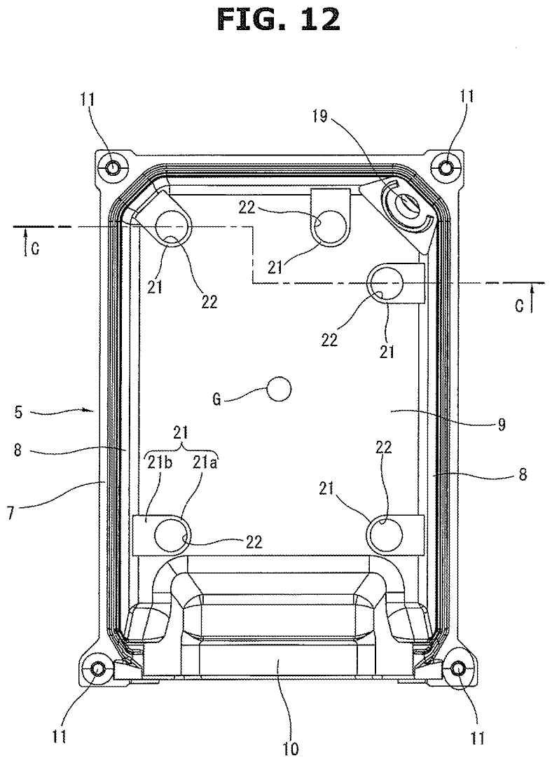

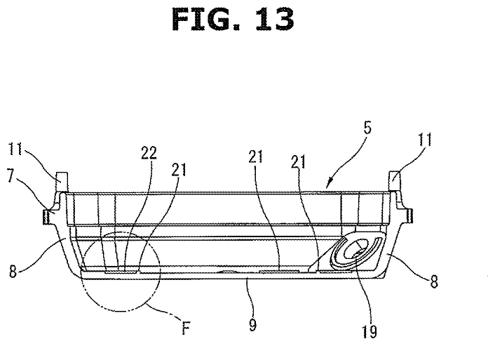

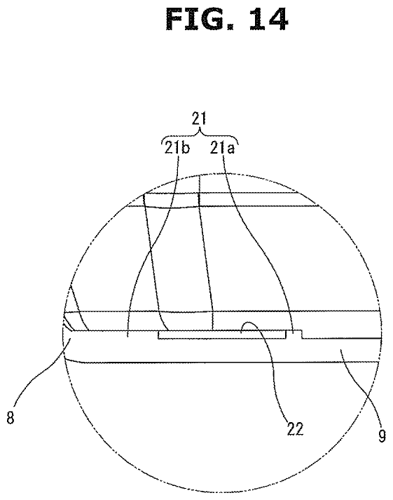

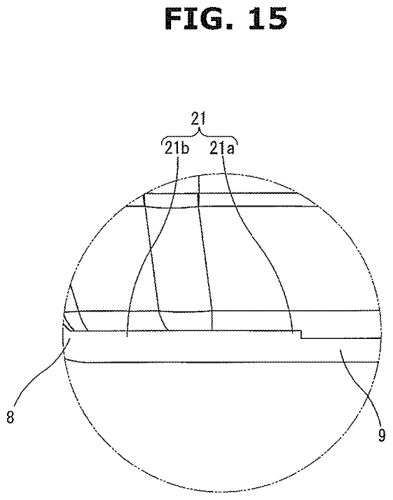

Next, the cover Sofa second embodiment in which an outline shape of the thick portion 21 is changed will be described. FIG. 12 is a plan view of the cover 5, viewed from its inside, of the second embodiment. FIG. 13 is a sectional view taken along a C-C line of FIG. 12. FIG. 14 is an enlarged sectional view of the thick portion 21. FIG. 15 is an enlarged sectional view of the thick portion 21 before contact with the ejection pin. The thick portion 21 of the cover 5 of the second embodiment has a shape in which the aforementioned thick portion 21 of the first embodiment is connected to the adjacent side wall 8.

That is, the thick portion 21 of the second embodiment is formed by a semicircle portion 21a and a rectangular portion 21b sandwiched by or enclosed with two parallel lines extending in a tangential direction from the semicircle portion 21a, and a tip of the rectangular portion 21b is connected to the side wall 8. That is, the thick portion 21 and the side wall 8 are molded into a continuous form. With this, the five thick portions 21 function as a kind of reinforcing member that strengthens the ceiling wall 9, thereby suppressing heat shrinkage of the ceiling wall 9 of the molded product and also making the ceiling wall 9 resistant to warp.

It is noted that although an area occupied by the thick portion 21 in plan view of the cover 5 is increased as compared with the first embodiment, in the same manner as the first embodiment, the electrolytic capacitors 17 is not arranged at a position that overlaps the thick portion 21 in plan view. Since the number of the electronic components which are arranged at an outer peripheral edge of the circuit board 3 is relatively small, an adverse effect on layout of the electronic components due to the increase in the area occupied by the thick portion 21 is small.

As in the first embodiment, the ejection pin presses against the thick portion 21, and as a result of the ejection pin pressing against the thick portion 21 that is molded as shown in FIG. 15, in the final molded product, as illustrated in FIG. 14, a circular dent 22 corresponding to the tip surface of the ejection pin is formed. A diameter of the semicircle portion 21a is greater than a diameter of the round bar-shaped ejection pin. That is, the thick portion 21 has a size that embraces or encompasses the ejection surface of the ejection pin.

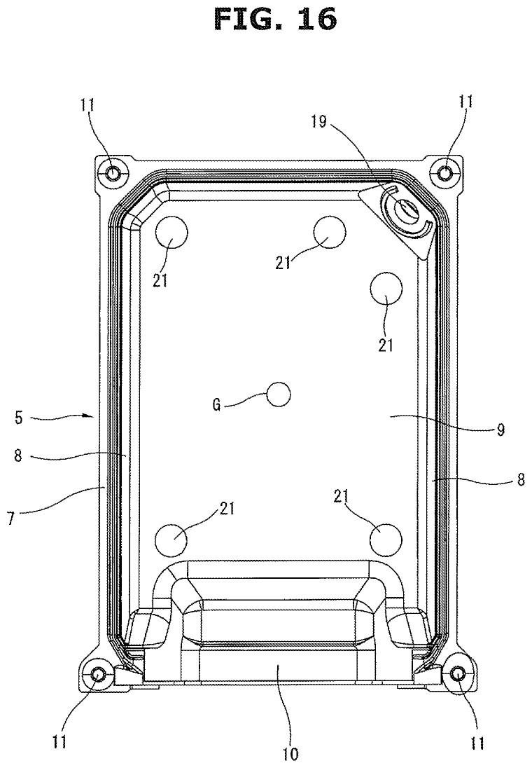

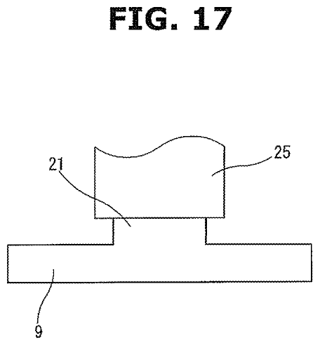

Next, the cover 5 of a third embodiment in which the outline shape of the thick portion 21 is smaller than the tip surface of the ejection pin will be described. FIG. 16 is a plan view of the cover 5, viewed from its inside, of the third embodiment. FIG. 17 is an explanatory drawing showing a dimensional relationship between the tip surface of an ejection pin 25 and the thick portion 21.

Also in this third embodiment, as illustrated in FIG. 16, a total of five circular thick portions 21 are arranged at the same positions as those of the first embodiment. Here, in the third embodiment, as depicted in FIG. 17, a diameter of the molded circular thick portion 21 is relatively smaller than a diameter of the ejection pin 25. That is, the thick portion 21 has a size that is embraced or encompassed by the ejection surface of the ejection pin 25.

Therefore, when the ejection pin 25 presses against the thick portion 21 during release of the molded product from the mold, the thick portion 21 is crushed or stamped over its entire surface, and a height of the thick portion 21 is reduced in the final molded product. For instance, if the thick portion 21 is set so that its height is finally close to 0, the electrolytic capacitor 17 can also be arranged at a position that overlaps the thick portion 21 in plan view, which increases degree of flexibility in layout of the electronic components.

It is noted that although the ejection pin is described as the round bar shape in each of the above embodiments, in the present invention, the ejection pin could have any shape such as a quadrangle in cross section, a polygon in cross section or an ellipse in cross section. Likewise, the outline shape of the thick portion 21 is not limited to the circular shape, but may be a quadrangle, a polygon or an ellipse.

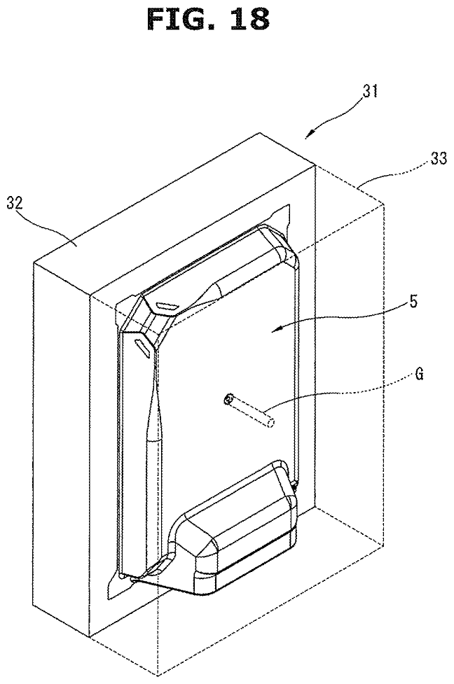

Next, FIG. 18 is a perspective view of a mold device 31 for molding the cover 5 of the first embodiment. This mold device 31 has a first mold 32 that is a so-called core mold and a second mold 33 that is a so-called cavity mold, and by both these molds, a space corresponding to a shape of the molded product, i.e. a cavity 34, is formed. Although the mold device 31 has a slide core etc. for forming the above-mentioned opening 19, it is omitted in the drawings. As described above, the gate G from which the molten resin from an injection device is injected is positioned at the center of the ceiling wall 9. Therefore, the molten resin coming from the gate G of the center of the ceiling wall 9 flows radially in the relatively narrow cavity 34 that forms the ceiling wall 9, and flows toward the heat caulking pins 11 arranged at the four corners which are the final arrival points of the resin material.

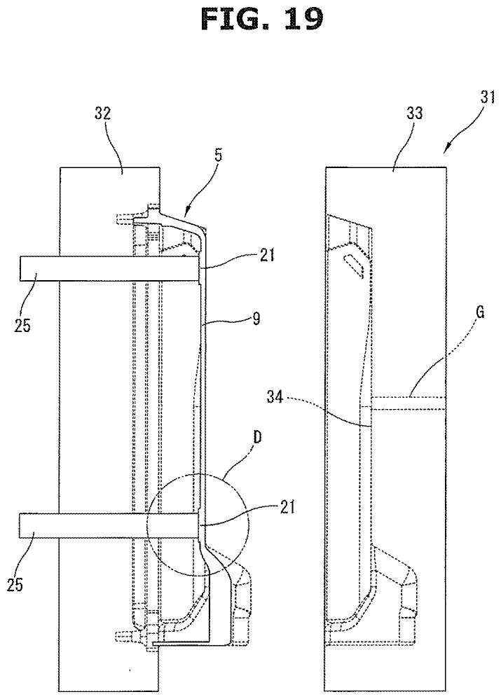

FIG. 19 is an explanatory drawing showing a state of the mold device 31 in which the molding is completed and the mold device 31 is opened. The inner surface of the cover 5 is molded by the first mold 32, and an outer surface of the cover 5 is molded by the second mold 33. The plurality of ejection pins 25 are provided with these ejection pins 25 penetrating the first mold 32. When the molded product is cooled to some extent, the molds 32 and 33 are opened, and the ejection pins 25 eject or push out the molded product in conjunction with this opening of the molds.

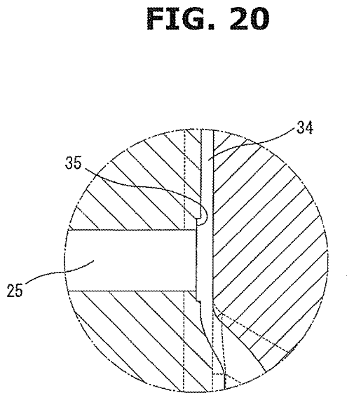

FIG. 20 is an enlarged view of a D-part of FIG. 19. As illustrated in this FIG. 20, a mold surface of the first mold 32 for molding the inner surface of the cover 5 is provided with disk-shaped recesses 35 for forming the respective thick portions 21. These recesses 35 are provided at positions that face the respective ejection pins 25, and are parts of the cavity 34 into which the resin material flows.

By performing the injection molding using such mold device 31, the cover 5 having the above-described thick portions 21 can be obtained.

Although the embodiments of the present invention are described in detail above, the present invention is not limited to the above embodiments, but includes various modifications. For instance, the cover member of the present invention is not limited to the cover of the controller, but can be widely applied to various cover members having the ceiling wall and the side walls.

As described above, a cover member of the present invention has a ceiling wall and side walls, the cover member is molded from synthetic resin material using a mold, and the cover member comprises: thick portions which are provided at a plurality of positions of the ceiling wall corresponding to respective positions of ejection by ejection pins when releasing the cover member from the mold and which locally protrude inward so as to be relatively thicker than an adjacent normal portion of the ceiling wall.

As a preferable aspect of the present invention, the thick portion has a size that encompasses an ejection surface of the ejection pin.

As another preferable aspect, the thick portion has a size that is encompassed by an ejection surface of the ejection pin.

Preferably, the thick portions are arranged on straight lines that connect a gate position and final arrival points of the resin material at a time of molding.

As another aspect, the cover member further comprises an opening at the side wall, and a pair of thick portions are arranged on both sides of a straight line that connects a center of the opening and a gate position at a time of molding.

As an example, the opening is positioned on the straight line that connects the gate position and a final arrival point of the resin material.

As a preferable aspect of the present invention, the thick portion is formed into a shape in which the thick portion and the side wall are connected together.

Further, a mold device of the present invention which molds the cover member as claimed in any one of the preceding claims 1 to 7, comprises: at least a first mold structured to mold an inner surface of the cover member and a second mold structured to mold an outer surface of the cover member, and the first mold has a plurality of ejection pins that eject and release the molded cover member from the first mold, and a mold surface of the first mold is provided, at positions corresponding to positions of the ejection pins, with recesses for forming the thick portions.

Moreover, an electronic device of the present invention has the cover member as claimed in any one of the preceding claims 1 to 7, a case combined with the cover member and a circuit board accommodated in a space formed by the cover member and the case and mounting thereon electronic components, and as compared with a height size of an electronic component whose height from the circuit board is a maximum among the electronic components, a distance from the circuit board at the thick portion up to a surface of the thick portion is set to be great.

1. A cover member having a ceiling wall and side walls, the cover member being molded from synthetic resin material using a mold, the cover member comprising:
thick portions which are provided at a plurality of positions of the ceiling wall corresponding to respective positions of ejection by ejection pins when releasing the cover member from the mold and which locally protrude inward so as to be relatively thicker than an adjacent normal portion of the ceiling wall.

2. The cover member as claimed in claim 1, wherein
the thick portion has a size that encompasses an ejection surface of the ejection pin.

3. The cover member as claimed in claim 1, wherein
the thick portion has a size that is encompassed by an ejection surface of the ejection pin.

4. The cover member as claimed in claim 1, wherein
the thick portions are arranged on straight lines that connect a gate position and final arrival points of the resin material at a time of molding.

5. The cover member as claimed in claim 1, further comprising:
an opening at the side wall, wherein
a pair of thick portions are arranged on both sides of a straight line that connects a center of the opening and a gate position at a time of molding.

6. The cover member as claimed in claim 5, wherein
the opening is positioned on the straight line that connects the gate position and a final arrival point of the resin material.

7. The cover member as claimed in claim 1, wherein
the thick portion is formed into a shape in which the thick portion and the side wall are connected together.

8. A mold device that molds the cover member as claimed in claim 1, comprising:
at least a first mold structured to mold an inner surface of the cover member and a second mold structured to mold an outer surface of the cover member, wherein
the first mold has a plurality of ejection pins that eject and release the molded cover member from the first mold, and
a mold surface of the first mold is provided, at positions corresponding to positions of the ejection pins, with recesses for forming the thick portions.

9. An electronic device comprising:
the cover member as claimed in claim 1;
a case combined with the cover member; and
a circuit board accommodated in a space formed by the cover member and the case and mounting thereon electronic components, wherein
as compared with a height size of an electronic component whose height from the circuit board is a maximum among the electronic components, a distance from the circuit board at the thick portion up to a surface of the thick portion is set to be great.
